(19) United States
(12) Patent Application Publication
(10) Pub. No.: US 2026/0005707 A1
(43) Pub. Date: Jan. 1, 2026

(54) TECHNOLOGIES FOR GENERATING DATA COMPRESSION DICTIONARIES

(71) Applicant: Intel Corporation, Santa Clara, CA (US)

(72) Inventors: Laurent COQUEREL, Limerick (IE); Fei Z. WANG, Shannon (IE); Smita KUMAR, Chandler, AZ (US); Qumrul AHSAN, Chandler, AZ (US); Giovanni CABIDDU, Shannon (IE); Mateusz POLROLA, Lodz (PL); Jusak EFFENDY, Roseville, CA (US)

(21) Appl. No.: 19/318,277

(22) Filed: Sep. 3, 2025

(51) Int. Cl. H03M 7/30

(52) U.S. Cl. CPC H03M 7/3088; H03M 7/3059

(57) ABSTRACT

Examples described herein relate to an accelerator configured to: based on receipt of a request to generate a dictionary: generate a dictionary for data compression based on data associated with the request and store the dictionary in a memory device and based on receipt of a second request to generate a second dictionary and compress second data. In some examples, generating the second dictionary for compression of the second data includes loading the second dictionary into a history buffer, compressing the second data, and storing the compressed second data into the memory device.

A processor can offload cryptographic and compression tasks to accelerator devices to reduce computational loads on the processor. To perform data compression to reduce a size of data, accelerator devices replace patterns or sequences of data with shorter representations. Dictionaries store patterns or sequences of data and corresponding shorter representations or codes. As the accelerator processes the data, the accelerator scans for sequences that match entries in the dictionary and when a match is found, the accelerator outputs the corresponding code instead of the longer data sequence. The extent of data compression depends on the extent to which the dictionary identifies data sequences that are replaced with shorter representations or codes.

### BRIEF DESCRIPTION OF THE DRAWINGS

FIG. 1 depicts an example system.

FIG. 2 depicts an example of a dictionary creation mode.

FIG. 3 depicts an example of a dictionary creation and data compression mode.

FIG. 4 shows an example process.

FIG. 5 depicts a system.

FIG. 6 depicts an example accelerator.

### DETAILED DESCRIPTION

Various examples offload, to an accelerator, (1) creating a dictionary dataset and (2) loading the dictionary into a history buffer and using the dictionary to compress data. For example, a process can issue a batch request to request to create a dictionary for a specified payload of data and/or utilize the dictionary to compress data. The request can define a format of dictionary for an accelerator to create (e.g., raw or formatted). The request can cause the accelerator to load the dictionary into a history buffer of the accelerator to compress data. The accelerator can generate different dictionaries for different data sets and compress different data sets using different dictionaries. For example, a first dictionary, used to compress a first data set, can be different from a second dictionary, used to compress a second data set. Offloading dictionary data creation to an accelerator for different data sets can potentially improve a compression ratio of data or ratio of the original data size to its compressed size, reduce utilization of a processor to generate dictionary, and/or reduce a time to generate a dictionary.

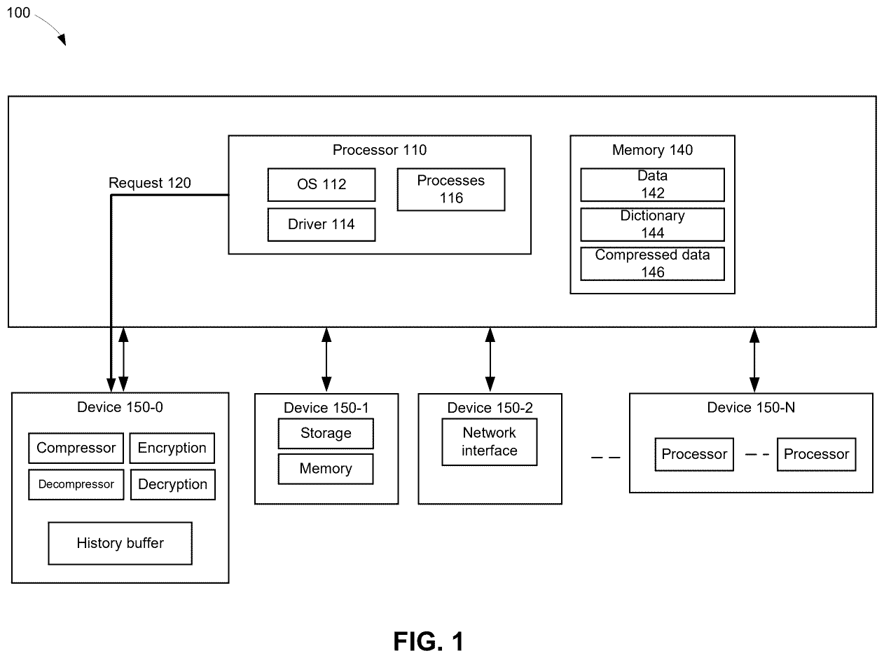

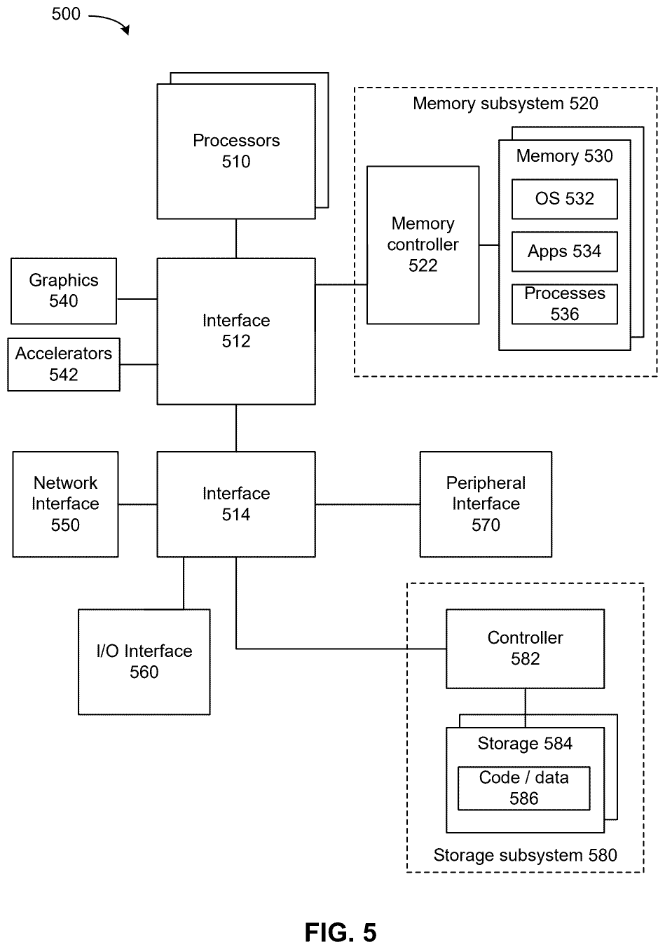

FIG. 1 depicts an example system. System 100 can include processor 110, memory 130, one or more of devices 150-0 to 150-N, where N is an integer, and other circuitry and software described at least with respect to FIGS. 5 and/or 6. In some examples, system 100 can be implemented in a semiconductor package. The semiconductor package can include metal, plastic, glass, and/or ceramic casing that covers and encapsulates one or more semiconductor devices or integrated circuits (e.g., processor 110, memory 140, or one or more of devices 150-0 to 150-N) and provides communications within or among the one or more semiconductor devices or integrated circuits.

Processor 110 can include one or more general purpose processors, including at least: a central processing unit (CPU), a processor core, graphics processing unit (GPU), neural processing unit (NPU), general purpose GPU (GPGPU), field programmable gate array (FPGA), application specific integrated circuit (ASIC), tensor processing unit (TPU), matrix math unit (MMU), or other circuitry. A processor core can include an execution core or computational engine that is capable of executing instructions. A core can access to its own cache and read only memory (ROM), or multiple cores can share a cache or ROM. Accelerator cores, slices, and/or cores can be homogeneous (e.g., same processing capabilities) and/or heterogeneous devices (e.g., different processing capabilities). A core can be sold or designed by Intel®, ARM®, Advanced Micro Devices, Inc. (AMD)®, Qualcomm®, IBM®, Nvidia®, Broadcom®, Texas Instruments®, or compatible with reduced instruction set computer (RISC) instruction set architecture (ISA) (e.g., RISC-V), among others.

In some examples, processor-executed operating system (OS) 112 or driver 114 can advertise capability of device 150-0 to perform (1) dictionary creation or (2) dictionary creation and compression or decompression of data based on created dictionary 142. For example, OS 112 can call an application programming interface (API) or issue a configuration to configure device 150-0 to perform (1) dictionary creation or (2) dictionary creation and compression or decompression of data based on created dictionary 142.

Processor 110 can execute processes 116 that can request packet processing, packet transmission, data compression, data decompression, data encryption, data decryption, data copying, or other operations to be performed by one or more of devices 150-0 to 150-N. Processes 116 can include one or more of: an application, process, thread, a virtual machine (VM), micro VM, container, microservice, virtual function (VF), virtual device, or other virtualized execution environment.

One or more of devices 150-0 to 150-N can perform operations offloaded from processor 110. Devices 150-0 to 150-N can include one or more of: a memory device, a storage device, a memory controller, a storage controller, a network interface device, or other circuitry, such as circuitry described with respect to FIGS. 5 and/or 6. A network interface device can include one or more of: a network interface controller (NIC), a remote direct memory access (RDMA)-enabled NIC, SmartNIC, router, switch, forwarding element, infrastructure processing unit (IPU), data processing unit (DPU), edge processing unit (EPU), or Amazon Web Services (AWS) Nitro Card. An edge processing unit (EPU) can include a network interface device that utilizes processors and accelerators (e.g., digital signal processors (DSPs), signal processors, or wireless specific accelerators for Virtualized radio access networks (vRANs), cryptographic operations, compression/decompression, and so forth). A Nitro Card can include various circuitry to perform compression, decompression, encryption, or decryption operations as well as circuitry to perform input/output (I/O) operations.

One or more of devices 150-0 to 150-N can perform data compression or decompression. In some cases, lossless or lossy compression and decompression schemes can be performed. Various compression and decompression schemes are available to be performed such as but not limited to Lempel Ziv (LZ) family of compression schemes including LZ77, LZ78, LZ4, Zstandard (ZSTD), DEFLATE, GZIP, XP10, and Snappy standards and derivatives, among others. A compression scheme can be chosen based on one or more of the following input stream characteristics: type and size of an input stream, a length of a character string pattern, a distance from a start of where the pattern is to be inserted to the beginning of where the pattern occurred previously, a gap between two pattern matches (including different or same patterns), standard deviation of a length of a pattern, standard deviation of a distance from a start of where the pattern is to be inserted to the beginning of where the pattern occurred previously, or standard deviation of a gap between two pattern matches.

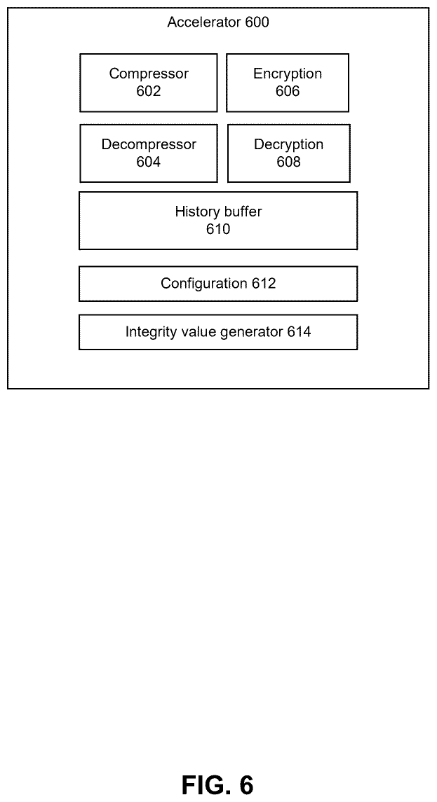

One or more of devices 150-0 to 150-N can include Intel® QuickAssist Technology (Intel® QAT). An example QAT is described at least with respect to FIG. 6. One or more of devices 150-0 to 150-N can include accelerator cores, which can be organized into slices. A slice can include a logical partition of accelerator core and a slice can be configured to handle specific types of workloads, such as cryptographic operations (e.g., encryption, decryption) or data compression. QAT can perform offloaded compression and decompression of data by applying one of multiple different compression formats (e.g., zstandard, DEFLATE, or others).

For example, one or more of processes 116 can issue request 120 to device 150-0 to perform creation of dictionary 144 and/or compress data 142. One or more of devices 150-0 to 150-N can load a created dictionary into a history buffer based on a command from process 116, without receipt of a command from driver 114. Request 120 can specify one or more of: output format of dictionary 144, one or more cleartext data 142 that is used to generate dictionary 144, mode of operation (e.g., create dictionary 144 and store dictionary 144 in memory 140 or create dictionary 144, load a dictionary into a history buffer, and compress data 142), generate and include security code on dictionary 144, a format of the dictionary (e.g., raw or formatted), or others. For example, security code can include a checksum calculated on a portion of dictionary 144, cyclic redundancy check (CRC) calculated on a portion of dictionary 144, hash calculation on a portion of dictionary 144, or others.

In some examples, process 116 can issue request 120 as a single batch that requests device 150-0 to (1) generate dictionary 144 on one or more user cleartext data entries of data 142 by specifying a memory address range or (2) generate dictionary 144 on one or more user cleartext data entries of data 142, load a dictionary into a history buffer, and compress one or more user cleartext data entries of data 142 based on dictionary 144. For example, data 142 can include one or more of: packet header, packet payload, artificial intelligence (AI) or machine learning (ML) training data, or others.

Dictionary creation can include a fixed function or a programmable offload engine processor analyzing input data with a match string. The match string can be one more characters in length (e.g., 3 bytes long as an example). The matching string can be compared to the input data as a sliding window. When the string is matched with the input data, a frequency counter can be incremented and a table is built that combines matching strings and frequencies. The dictionary would be made of the matching strings with the highest frequencies.

For example, for an input data string: ACK AGE BACK CAGE DAGO HACK JACK KAGO RACK RAGE PACK PAGE SAGE SAGO SMACK, a table can be as follows:

| Matching string | Frequency |
|---|---|
| ACK | 7 |
| AGE | 5 |
| AGO | 3 |

The dictionary would be “ACK AGE AGO”.

For example, request 120 can specify whether to create a raw or formatted dictionary. A raw dictionary can include cleartext. Raw dictionary compression can be a lossless technique, where no information is lost during the compression and decompression processes, and the original data can be reconstructed without modification. A formatted dictionary can include a specific format depending on a utilized compression standard. A formatted dictionary can include a magic number for a frame, dictionary identifier, entropy table, and dictionary content (e.g., clear text). An example format of dictionary can include Zstandard Compression Format, version 0.4.4 (March 2025) and variations thereof. Offloading creation of formatted dictionary creation to an accelerator (e.g., device 150-0) can reduce computational burden on a processor that executes a process to generate a formatted dictionary from a raw dictionary.

Processor 110 can access one or more of devices 150-0 to 150-N by die-to-die communications; chipset-to-chipset communications; circuit board-to-circuit board communications; package-to-package communications; and/or server-to-server communications. Die-to-die communications can utilize Embedded Multi-Die Interconnect Bridge (EMIB) or an interposer. Components of FIG. 1 (e.g., processor 110, memory 140, devices 150-0 to 150-N, or others) can be enclosed in one or more semiconductor packages. A semiconductor package can include metal, plastic, glass, and/or ceramic casing that encompass and provide communications within or among one or more semiconductor devices or integrated circuits.

In some examples, system 100 can be implemented as part of a system-on-a-chip (SoC). Various examples of system 100 can be implemented as a discrete device, in a die, in a chip, on a die or chip mounted to a circuit board, in a package, or between multiple packages, in a server, in a CPU socket, or among multiple servers.

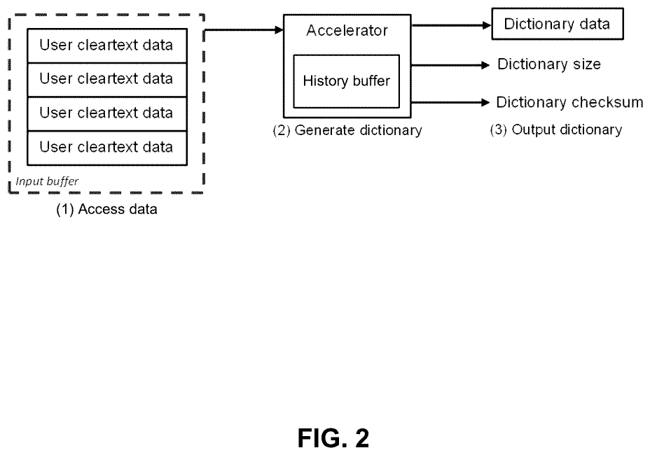

FIG. 2 depicts an example of a dictionary creation mode. At (1), data (e.g., data 142) can be accessed by an accelerator (e.g., device 150-0). At (2), as the accelerator is configured to operate in dictionary create mode, the accelerator can create a dictionary based on the data. During dictionary creation mode, the accelerator analyzes the batch payload data and identifies a subset of data to represent the dictionary and loads the dictionary into the history buffer. Dictionary can include frequently occurring patterns, strings, or phrases. If requested, accelerator can generate a security code on the dictionary.

At (3), the accelerator can output the dictionary in the requested format (e.g., raw or formatter) to memory for access by the requester (e.g., process 116) or for subsequent use to compress data or decompress data. The dictionary size and dictionary security code (e.g., checksum) can be provided to a requester (e.g., process 116) and a starting memory address of the dictionary data in memory (e.g., memory 140).

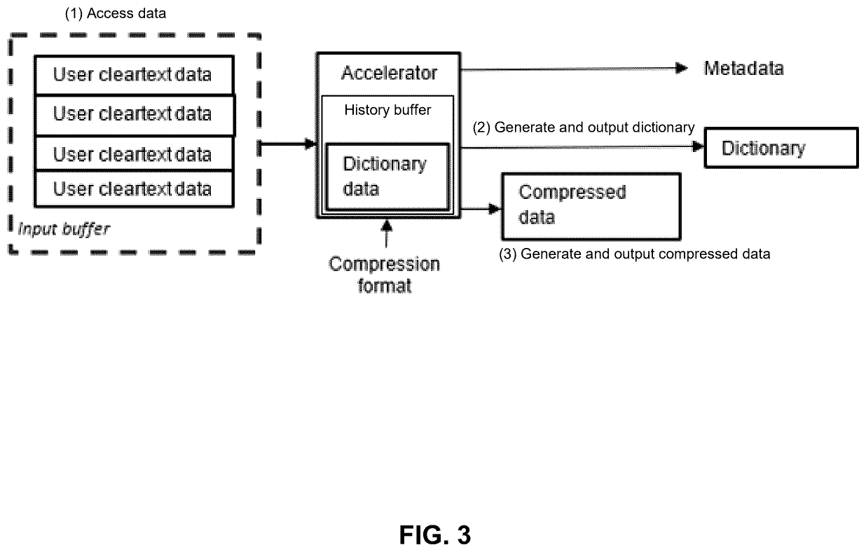

FIG. 3 depicts an example of a dictionary creation and data compression mode. At (1), data (e.g., data 142) can be accessed by an accelerator (e.g., device 150-0). At (2), as the accelerator is configured to operate in dictionary create and data compression mode, the accelerator can create a dictionary based on the data. To generate the dictionary, the accelerator can perform operations described at least with respect to (2) of FIG. 2. The accelerator can store the dictionary in memory or cache and access the dictionary and store the dictionary in a history buffer to compress the accessed data. The accelerator can access the dictionary and store the dictionary into a history buffer without a specific request to read the dictionary from a requester process or device driver for the accelerator. A history buffer can be used to store clear text data or plain text data (“history data”) that has been processed by the accelerator. The history buffer acts as a sliding window/circular queue.

At (3), the accelerator can compress the data using the generated dictionary. The accelerator can indicate to the requester (e.g., process 116) a starting memory address of compressed data in memory (e.g., memory 140), a starting memory address of generated dictionary in memory (e.g., memory 140), metadata of a counter of input data (e.g., number of bytes of data prior to compression) that were compressed, metadata of a counter of data that was generated from compression (e.g., number of bytes of generated compressed data), a security code for the dictionary (e.g., checksum or CRC), operation status (e.g., completed, error, fail) or others. In some examples, the creation of the dictionary is synchronous with data compression.

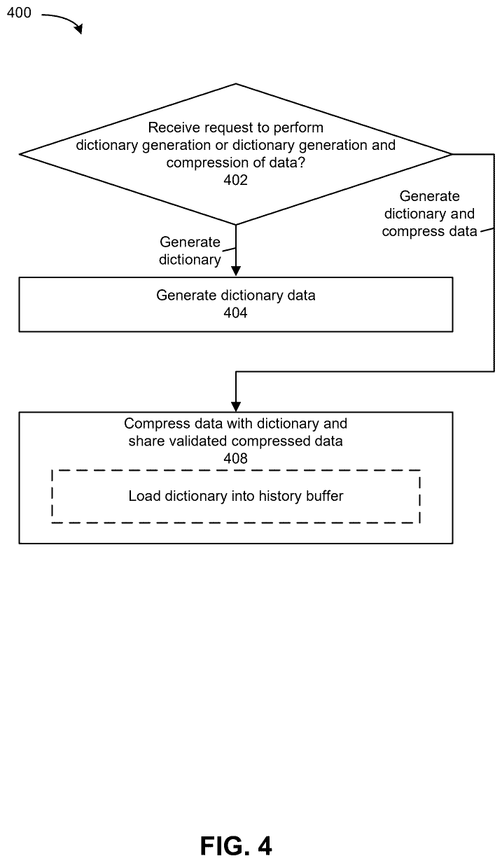

FIG. 4 shows an example process to create a dictionary based on input data and the compression operation. The process can be performed by an accelerator. At 402, a determination can be made if the accelerator is to perform dictionary generation operation or generate a dictionary followed by a compression operation. Based on the accelerator receiving a request to perform dictionary generation, at 404, the accelerator can generate dictionary data on data identified in a request to generate a dictionary. The accelerator can store the dictionary in memory and indicate to a requester that the dictionary is available. At 406, based on the accelerator receiving a request to perform dictionary generation and compress data, the accelerator can generate a dictionary for the data and subsequently compress the data. The accelerator can store the compressed data in a memory starting at a memory address. In some examples, the accelerator can validate integrity of a compression operation by: generate an integrity value on the data (e.g., checksum, hash value, or cyclic redundancy check (CRC)) and record a length of the data prior to compression, decompress the compressed data, generate another integrity value on the decompressed data, determine a length of the decompressed data. The accelerator can share a memory address of the compressed data with the requester process based on matching of the integrity value with the previously generated integrity value.

FIG. 5 depicts a system. The system can use examples to generate a dictionary or generate a dictionary and perform data compression, as described herein. In some examples, processor 510, graphics 540, one or more of accelerators 542, and/or network interface 550 can generate a dictionary or generate a dictionary and perform data compression, as described herein. System 500 includes processor 510, which provides processing, operation management, and execution of instructions for system 500. Processor 510 can include any type of microprocessor, central processing unit (CPU), graphics processing unit (GPU), processing core, or other processing hardware to provide processing for system 500, or a combination of processors. Processor 510 controls the overall operation of system 500, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 500 includes interface 512 coupled to processor 510, which can represent a higher speed interface or a high throughput interface for system components that needs higher bandwidth connections, such as memory subsystem 520 or graphics interface components 540, or accelerators 542. Interface 512 represents an interface circuit, which can be a standalone component or integrated onto a processor die.

Accelerators 542 can be a fixed function or programmable offload engine that can be accessed or used by a processor 510. For example, an accelerator among accelerators 542 can provide data compression (DC) capability, cryptography services such as public key encryption (PKE), cipher, hash/authentication capabilities, decryption, or other capabilities or services. In some cases, accelerators 542 can be integrated into a CPU socket (e.g., a connector to a motherboard or circuit board that includes a CPU and provides an electrical interface with the CPU). For example, accelerators 542 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 542 can provide multiple neural networks, CPUs, processor cores, general purpose graphics processing units, or graphics processing units can be made available for use by artificial intelligence (AI) or machine learning (ML) models. For example, the AI model can use or include one or more of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 520 represents the main memory of system 500 and provides storage for code to be executed by processor 510, or data values to be used in executing a routine. Memory subsystem 520 can include one or more memory devices 530 such as read-only memory (ROM), flash memory, one or more varieties of random access memory (RAM) such as static random-access memory (SRAM), dynamic random-access memory (DRAM), or other memory devices, or a combination of such devices. Memory 530 stores and hosts, among other things, operating system (OS) 532 to provide a software platform for execution of instructions in system 500. Additionally, applications 534 can execute on the software platform of OS 532 from memory 530. Applications 534 represent programs that have their own operational logic to perform execution of one or more functions. Processes 536 represent agents or routines that provide auxiliary functions to OS 532 or one or more applications 534 or a combination. OS 532, applications 534, and processes 536 provide software logic to provide functions for system 500. In one example, memory subsystem 520 includes memory controller 522, which is a memory controller to generate and issue commands to memory 530. It will be understood that memory controller 522 could be a physical part of processor 510 or a physical part of interface 512. For example, memory controller 522 can be an integrated memory controller, integrated onto a circuit with processor 510.

In some examples, OS 532 can be Linux®, Windows® Server or personal computer, FreeBSD®, Android®, MacOS®, iOS®, VMware vSphere, openSUSE, RHEL, CentOS, Debian, Ubuntu, or any other operating system. The OS and driver can execute on a CPU sold or designed by Intel®, ARM®, AMD®, Qualcomm®, IBM®, Texas Instruments®, among others.

In some examples, OS 532 or driver can advertise capability of at least one of accelerators 542 to perform generation of a dictionary or generation of a dictionary and data compression, as described herein. In some examples, OS 532 or driver can enable or disable use at least one of accelerators 542 to perform generation of a dictionary or generation of a dictionary and data compression.

While not specifically illustrated, it will be understood that system 500 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, system 500 includes interface 514, which can be coupled to interface 512. In one example, interface 514 represents an interface circuit, which can include standalone components and integrated circuitry. In one example, multiple user interface components or peripheral components, or both, couple to interface 514. Network interface 550 provides system 500 the ability to communicate with remote devices (e.g., servers or other computing devices) over one or more networks. In some examples, network interface 550 can refer to one or more of: a network interface controller (NIC), a remote direct memory access (RDMA)-enabled NIC, SmartNIC, router, switch, forwarding element, infrastructure processing unit (IPU), data processing unit (DPU), or network-attached appliance.

Network interface 550 can include an Ethernet adapter, wireless interconnection components, cellular network interconnection components, USB (universal serial bus), or other wired or wireless standards-based or proprietary interfaces. Network interface 550 can transmit data to a device that is in the same data center or rack or a remote device, which can include sending data stored in memory.

Some examples of network interface 550 are part of an Infrastructure Processing Unit (IPU) or data processing unit (DPU) or utilized by an IPU or DPU. An xPU can refer at least to an IPU, DPU, GPU, GPGPU, or other processing units (e.g., accelerator devices). An IPU or DPU can include a network interface with one or more programmable pipelines or fixed function processors to perform offload of operations that could have been performed by a CPU. The IPU or DPU can include one or more memory devices. In some examples, the IPU or DPU can perform virtual switch operations, manage storage transactions (e.g., compression, cryptography, virtualization), and manage operations performed on other IPUs, DPUs, servers, or devices.

Some examples of network interface 550 can include a programmable packet processing pipeline with one or multiple consecutive stages of match-action circuitry. The programmable packet processing pipeline can be programmed using one or more of: Protocol-independent Packet Processors (P4), Software for Open Networking in the Cloud (SONIC), Broadcom® Network Programming Language (NPL), NVIDIA® CUDA®, NVIDIA® DOCA™, Data Plane Development Kit (DPDK), OpenDataPlane (ODP), Infrastructure Programmer Development Kit (IPDK), x86 compatible executable binaries or other executable binaries, or others.

In one example, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include any hardware interface not specifically mentioned above. Peripherals refer generally to devices that connect dependently to system 500. A dependent connection is one where system 500 provides the software platform or hardware platform or both on which operation executes, and with which a user interacts.

In one example, system 500 includes storage subsystem 580 to store data in a nonvolatile manner. In one example, in certain system implementations, at least certain components of storage 580 can overlap with components of memory subsystem 520. Storage subsystem 580 includes storage device(s) 584, which can be or include any conventional medium for storing large amounts of data in a nonvolatile manner, such as one or more magnetic, solid state, or optical based disks, or a combination. Storage 584 holds code or instructions and data 586 in a persistent state (e.g., the value is retained despite interruption of power to system 500). Storage 584 can be generically considered to be a “memory,” although memory 530 is typically the executing or operating memory to provide instructions to processor 510. Whereas storage 584 is nonvolatile, memory 530 can include volatile memory (e.g., the value or state of the data is indeterminate if power is interrupted to system 500). In one example, storage subsystem 580 includes controller 582 to interface with storage 584. In one example controller 582 is a physical part of interface 514 or processor 510 or can include circuits or logic in both processor 510 and interface 514.

A volatile memory is memory whose state (and therefore the data stored in it) is indeterminate if power is interrupted to the device. A non-volatile memory (NVM) device is a memory whose state is determinate even if power is interrupted to the device.

In an example, system 500 can be implemented using interconnected compute sleds of processors, memories, storages, network interfaces, and other components. High speed interconnects can be used such as: Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Peripheral Component Interconnect express (PCIe), Intel QuickPath Interconnect (QPI), Intel Ultra Path Interconnect (UPI), Intel On-Chip System Fabric (IOSF), Omni-Path, Compute Express Link (CXL), HyperTransport, high-speed fabric, NVLink, Advanced Microcontroller Bus Architecture (AMBA) interconnect, OpenCAPI, Gen-Z, Infinity Fabric (IF), Cache Coherent Interconnect for Accelerators (CCIX), 3GPP Long Term Evolution (LTE) (4G), 3GPP 5G, and variations thereof. Data can be copied or stored to virtualized storage nodes or accessed using a protocol such as NVMe over Fabrics (NVMe-oF) or NVMe.

Communications between devices can take place using a network, interconnect, or circuitry that provides chipset-to-chipset communications, die-to-die communications, packet-based communications, communications over a device interface (e.g., PCIe, CXL, UPI, or others), fabric-based communications, and so forth. A die-to-die communications can be consistent with Embedded Multi-Die Interconnect Bridge (EMIB).

FIG. 6 depicts an example accelerator. Accelerator 600 can utilize compressor 602 to compress clear text data into a format specified by configuration 612 or perform data decompression 604 on data in a format specified by configuration 612 to clear text. Various examples of compression and decompression standards include at least Lempel Ziv (LZ) family of compression schemes including LZ77, LZ78, LZ4, Zstandard (ZSTD), DEFLATE, GZIP, XP10, and Snappy standards. To compress data, compressor 602 can store a dictionary into history buffer 610 to identify strings of characters to replace in data. Integrity value generator 614 can generate a security code on a portion of a dictionary or data. A security code can include a cyclic redundancy check (CRC), hash calculation, or checksum. Accelerator 600 can utilize encryption 606 to encrypt cleartext or compressed data based on a specification in configuration 612. Accelerator 600 can utilize decryption 608 to decrypt data based on a specification in configuration 612. Configuration 612 can specify a standard of data encryption/decryption, including at least Triple Data Encryption Standard (3DES), Advanced Encryption Standard (AES), Digital Signature Algorithm (DSA), Rivest-Shamir-Adleman (RSA) algorithm, Elliptic Curve Digital Signature Algorithm (ECDSA), Elliptic Curve Cryptography (ECC), or others.

Examples herein may be implemented in various types of computing and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, a blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. A processor can be one or more combination of a hardware state machine, digital control logic, central processing unit, or any hardware, firmware and/or software elements.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner, or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission, or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. For example, descriptions using the terms “connected” and/or “coupled” may indicate that two or more elements are in direct physical or electrical contact. The term “coupled,” however, may also mean that two or more elements are not in direct contact, but yet still co-operate or interact.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal (e.g., active-low or active-high). The terms “follow” or “after” can refer to immediately following or following after some other event or events. Other sequences of operations may also be performed according to alternative embodiments. Furthermore, additional operations may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to be present. Additionally, conjunctive language such as the phrase “at least one of X, Y, and Z,” unless specifically stated otherwise, should also be understood to mean X, Y, Z, or any combination thereof, including “X, Y, and/or Z.’”

Illustrative examples of the devices, systems, and methods disclosed herein are provided below. An embodiment of the devices, systems, and methods may include any one or more, and any combination of, the examples described below.

Example 1 includes one or more examples and includes an apparatus that includes: an interface and a circuitry, coupled to the interface, to: based on receipt of a request to generate a dictionary: generate a dictionary for data compression based on data associated with the request and store the dictionary in a memory device and based on receipt of a second request to generate a second dictionary and compress second data: generate the second dictionary for compression of the second data, load the second dictionary into a history buffer, compress the second data, and store the compressed second data into the memory device.

Example 2 includes one or more examples, wherein: the request is to specify whether to output a dictionary in a raw or a formatted format.

Example 3 includes one or more examples, wherein: based on a third request to compress the data, the circuitry is to compress the data using the dictionary.

Example 4 includes one or more examples, wherein: for the request, the circuitry is to perform operations offloaded from a processor of dictionary creation and for the second request, the circuitry is to perform operations offloaded from the processor of dictionary creation, dictionary loading into a history buffer, and data compression.

Example 5 includes one or more examples, wherein: the circuitry is accessible by a processor via device interface and wherein the circuitry comprises one or more of: a field programmable gate array (FPGA) or an application specific integrated circuit (ASIC).

Example 6 includes one or more examples, and includes a method comprising: based on a request, performing, by an accelerator, a combination of generating a dictionary on data and compressing the data and storing the compressed data into memory.

Example 7 includes one or more examples, wherein: the request specifies whether to output a dictionary in a raw or a formatted format.

Example 8 includes one or more examples, and includes compressing the data, by the accelerator, using the dictionary.

Example 9 includes one or more examples, and includes performing operations offloaded from a processor of dictionary creation.

Example 10 includes one or more examples, and includes based on receipt of a second request to generate a second dictionary: generating, by the accelerator, the second dictionary for data compression based on second data associated with the second request and store the second dictionary in the memory.

Example 11 includes one or more examples, and includes for the request, performing operations offloaded from a processor of second dictionary creation and second data compression.

Example 12 includes one or more examples, wherein: the accelerator comprises one or more of: a field programmable gate array (FPGA) or an application specific integrated circuit (ASIC).

Example 13 includes one or more examples, and includes at least one non-transitory computer-readable medium, comprising instructions stored thereon, that if executed by one or more processors, cause the one or more processors to: execute an operating system (OS) to configure a mode of operation of an accelerator to: for a first request, perform operations offloaded from a processor of dictionary creation based on first data and for a second request, perform operations offloaded from the processor of second dictionary creation based on second data, loading of the second dictionary into a history buffer, and compression of second data.

Example 14 includes one or more examples, wherein: the first request specifies whether to store the dictionary in raw or formatted format.

Example 15 includes one or more examples, and includes instructions stored thereon, that if executed by one or more processors, cause the one or more processors to: based on a third request to compress third data, compress the third data using the second dictionary.

Example 16 includes one or more examples, wherein: the accelerator is accessible by a processor via device interface and wherein the accelerator comprises one or more of: a field programmable gate array (FPGA) or an application specific integrated circuit (ASIC).

1. An apparatus comprising:
an interface and
a circuitry, coupled to the interface, to:
based on receipt of a request to generate a dictionary:
generate a dictionary for data compression based on data associated with the request and store the dictionary in a memory device and
based on receipt of a second request to generate a second dictionary and compress second data:
generate the second dictionary for compression of the second data, load the second dictionary into a history buffer, compress the second data, and store the compressed second data into the memory device.

2. The apparatus of claim 1, wherein:
the request is to specify whether to output a dictionary in a raw or a formatted format.

3. The apparatus of claim 1, wherein:
based on a third request to compress the data, the circuitry is to compress the data using the dictionary.

4. The apparatus of claim 1, wherein:
for the request, the circuitry is to perform operations offloaded from a processor of dictionary creation and
for the second request, the circuitry is to perform operations offloaded from the processor of dictionary creation, dictionary loading into a history buffer, and data compression.

5. The apparatus of claim 1, wherein the circuitry is accessible by a processor via device interface and wherein the circuitry comprises one or more of: a field programmable gate array (FPGA) or an application specific integrated circuit (ASIC).

6. A method comprising:
based on a request, performing, by an accelerator, a combination of generating a dictionary on data and compressing the data and storing the compressed data into memory.

7. The method of claim 6, wherein:
the request specifies whether to output a dictionary in a raw or a formatted format.

8. The method of claim 6, comprising:
compressing the data, by the accelerator, using the dictionary.

9. The method of claim 6, comprising:
performing operations offloaded from a processor of dictionary creation.

10. The method of claim 6, comprising:
based on receipt of a second request to generate a second dictionary:
generating, by the accelerator, the second dictionary for data compression based on second data associated with the second request and store the second dictionary in the memory.

11. The method of claim 10, comprising:
for the request, performing operations offloaded from a processor of second dictionary creation and second data compression.

12. The method of claim 10, wherein the accelerator comprises one or more of: a field programmable gate array (FPGA) or an application specific integrated circuit (ASIC).

13. At least one non-transitory computer-readable medium, comprising instructions stored thereon, that if executed by one or more processors, cause the one or more processors to:
execute an operating system (OS) to configure a mode of operation of an accelerator to:
for a first request, perform operations offloaded from a processor of dictionary creation based on first data and
for a second request, perform operations offloaded from the processor of second dictionary creation based on second data, loading of the second dictionary into a history buffer, and compression of second data.

14. The non-transitory computer-readable medium of claim 13, wherein the first request specifies whether to store the dictionary in raw or formatted format.

15. The non-transitory computer-readable medium of claim 13, comprising instructions stored thereon, that if executed by one or more processors, cause the one or more processors to:
based on a third request to compress third data, compress the third data using the second dictionary.

16. The non-transitory computer-readable medium of claim 13, wherein:
the accelerator is accessible by a processor via device interface and wherein the accelerator comprises one or more of: a field programmable gate array (FPGA) or an application specific integrated circuit (ASIC).
